(19) United States
(12) Patent Application Publication
(10) Pub. No.: US 2025/0030357 A1
(43) Pub. Date: Jan. 23, 2025

(54) METHOD AND APPARATUS FOR DETERMINING TURN-OFF NEGATIVE VOLTAGE OF SWITCHING TRANSISTOR, AND SWITCHING TRANSISTOR DRIVE CONTROL CIRCUIT

(71) Applicants: ANHUI WELLING AUTO PARTS CORPORATION LIMITED, Hefei (CN); GUANGDONG WELLING AUTO PARTS CORPORATION LIMITED, Foshan (CN)

(72) Inventors: Hongkang SHI, Hefei (CN); Junlong LI, Hefei (CN); Feixiang QIN, Hefei (CN)

(73) Assignees: ANHUI WELLING AUTO PARTS CORPORATION LIMITED, Hefei (CN); GUANGDONG WELLING AUTO PARTS CORPORATION LIMITED, Foshan (CN)

(21) Appl. No.: 18/903,455

(22) Filed: Oct. 1, 2024

Related U.S. Application Data
(63) Continuation of application No. PCT/CN2023/078880, filed on Feb. 28, 2023.

(30) Foreign Application Priority Data
Apr. 6, 2022 (CN) 202210360280.1

(51) Int. Cl. H02M 7/5387; G01R 31/26; H02M 1/00; H02M 1/08

(52) U.S. Cl. CPC H02M 7/53871; G01R 31/2621; H02M 1/0016; H02M 1/08

(57) ABSTRACT

A method and an apparatus for determining a turn-off negative voltage of a switching transistor are provided. The method includes: determining first and second turn-off negative voltage models; inputting acquired turn-off and turn-on gate resistances of the switching transistor, an acquired bus voltage, and an acquired minimum turn-on voltage of the switching transistor into the first model to obtain a turn-off negative voltage upper limit absolute value of the switching transistor; inputting the acquired turn-off and turn-on gate resistances of the switching transistor, the acquired bus voltage, and an acquired maximum bearable negative voltage absolute value of the switching transistor into the second model to obtain a turn-off negative voltage lower limit absolute value of the switching transistor; and determining a turn-off negative voltage interval of the switching transistor based on the turn-off negative voltage upper limit absolute value and the turn-off negative voltage lower limit absolute value.

### CROSS-REFERENCE TO RELATED APPLICATIONS

This application is a continuation application of PCT International Application No. PCT/CN2023/078880 filed on Feb. 28, 2023, which claims priority to and benefits of Chinese Patent Application No. 202210360280.1, entitled “METHOD AND APPARATUS FOR DETERMINING TURN-OFF VOLTAGE OF SWITCHING TRANSISTOR, AND SWITCHING TRANSISTOR DRIVE CONTROL CIRCUIT” and filed on Apr. 6, 2022, the entire contents of each of which are incorporated herein by reference for all purposes. No new matter has been introduced.

### FIELD

The present disclosure relates to the field of inverter technologies, and more particularly, to a method and an apparatus for determining a turn-off negative voltage of a switching transistor, and a switching transistor drive control circuit.

### BACKGROUND

With the gradual improvement of the living standard of people, more vehicles enter thousands of households to provide convenience for t raveling. In the related art, a silicon-carbide Metal Oxide Semiconductor (MOS) transistor is used in vehicle compressor inverter system of a high input voltage to reduce loss and improve efficiency of the inverter. However, the silicon-carbide MOS transistor has the problem of being easily turned on mistakenly.

### SUMMARY

The present disclosure aims to solve one of the technical problems in the related art at least to some extent. To this end, embodiments of the present disclosure is to provide a method for determining a turn-off negative voltage of a switching transistor, which can accurately determine a turn-off negative voltage interval of the switching transistor. Therefore, when a negative voltage turn-off control is performed on the switching transistor by using the turn-off negative voltage interval, the switching transistor can be effectively prevented from being turned on mistakenly, and the switching transistor can be protected, which can prolong service life of the switching transistor.

Embodiments of the present disclosure is further to provide an apparatus for determining a turn-off negative voltage of a switching transistor.

Embodiments of the present disclosure is further to provide an inverter.

Embodiments of the present disclosure is further to provide a computer-readable storage medium.

Embodiments of the present disclosure is further to provide a switching transistor drive control circuit.

Embodiments of the present disclosure is further to provide a motor control system.

Embodiments of the present disclosure is further to provide a compressor.

Embodiments of the present disclosure is further to provide a vehicle.

Embodiments of the present disclosure provide a method for determining a turn-off negative voltage of a switching transistor. The method includes: determining a first turn-off negative voltage model and a second turn-off negative voltage model; acquiring a turn-off gate resistance and a turn-on gate resistance of the switching transistor, a bus voltage, and a minimum turn-on voltage and a maximum bearable negative voltage absolute value of the switching transistor; inputting the turn-off gate resistance, the turn-on gate resistance, the bus voltage, and the minimum turn-on voltage into the first turn-off negative voltage model to obtain a turn-off negative voltage upper limit absolute value of the switching transistor, and inputting the turn-off gate resistance, the turn-on gate resistance, the bus voltage, and the maximum bearable negative voltage absolute value into the second turn-off negative voltage model to obtain a turn-off negative voltage lower limit absolute value of the switching transistor; and determining a turn-off negative voltage interval of the switching transistor based on the turn-off negative voltage upper limit absolute value and the turn-off negative voltage lower limit absolute value.

In the method for determining the turn-off negative voltage of the switching transistor according to the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when a negative voltage turn-off control is performed on the switching transistor by using the turn-off negative voltage interval, the switching transistor can be effectively prevented from being turned on mistakenly, and the switching transistor can be protected, which can prolong service life of the switching transistor.

In some embodiments of the present disclosure, the first turn-off negative voltage model is expressed as V_{SS_min}-λ₁*f₁(R_{G_on}, R_{G_off}, V_{DC})−Vₜₕ, where V_{SS_min} represents the turn-off negative voltage upper limit absolute value, λ₁ represents a first derating parameter, f₁(R_{G_on}, R_{G_off}, V_{DC}) represents a function expression corresponding to the first turn-off negative voltage model, R_{G_on} represents the turn-on gate resistance, R_{G_off} represents the turn-off gate resistance, V_{DC} represents the bus voltage, and Vₜₕ represents the minimum turn-on voltage.

In some embodiments of the present disclosure, the second turn-off negative voltage model is expressed as V_{SS_max}=V_{GS_max}−λ₂*f₂(R_{G_on}, R_{G_off}, V_{DC}), where V_{SS_max} represents the turn-off negative voltage lower limit absolute value, λ₂ represents a second derating parameter, f₂(R_{G_on}, R_{G_off}, V_{DC}) represents a function expression corresponding to the second turn-off negative voltage model, R_{G_on} represents the turn-on gate resistance, R_{G_off} represents the turn-off gate resistance, V_{DC} represents the bus voltage, and V_{GS_max} represents the maximum bearable negative voltage absolute value.

In some embodiments of the present disclosure, the determining the turn-off negative voltage interval of the switching transistor based on the turn-off negative voltage upper limit absolute value and the turn-off negative voltage lower limit absolute value includes: setting a negative value of the turn-off negative voltage upper limit absolute value as a turn-off negative voltage upper limit voltage, and setting a negative value of the turn-off negative voltage lower limit absolute value as a lower limit voltage of the turn-off negative voltage; and determining the turn-off negative voltage interval based on the upper limit voltage of the turn-off negative voltage and the lower limit voltage of the turn-off negative voltage.

In some embodiments of the present disclosure, the switching transistor is a silicon-carbide Metal Oxide Semiconductor (MOS) transistor.

Embodiments of the present disclosure further provide an apparatus for determining a turn-off negative voltage of a switching transistor. The apparatus includes: a first determining module configured to determine a first turn-off negative voltage model and a second turn-off negative voltage model; an acquiring module configured to acquire a turn-off gate resistance and a turn-on gate resistance of the switching transistor, a bus voltage, and a minimum turn-on voltage and a maximum bearable negative voltage absolute value of the switching transistor; and a second determining module configured to: input the turn-off gate resistance, the turn-on gate resistance, the bus voltage, and the minimum turn-on voltage into the first turn-off negative voltage model to obtain a turn-off negative voltage upper limit absolute value of the switching transistor; input the turn-off gate resistance, the turn-on gate resistance, the bus voltage, and the maximum bearable negative voltage absolute value into the second turn-off negative voltage model to obtain a turn-off negative voltage lower limit absolute value of the switching transistor; and determine a turn-off negative voltage interval of the switching transistor based on the turn-off negative voltage upper limit absolute value and the turn-off negative voltage lower limit absolute value.

In the apparatus for determining the turn-off negative voltage of the switching transistor according to the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when the negative voltage turn-off control is performed on the switching transistor by using the turn-off negative voltage interval, the switching transistor can be effectively prevented from being turned on mistakenly, and the switching transistor can be protected, which can prolong service life of the switching transistor.

Embodiments of the present disclosure further provide an inverter. The inverter includes a memory, a processor, and a program for determining a turn-off negative voltage of a switching transistor stored on the memory and executable on the processor. The processor is configured to implement, when executing the program for determining the turn-off negative voltage of the switching transistor, the method for determining the turn-off negative voltage of the switching transistor according to any one of the above-mentioned embodiments.

In the inverter of the embodiments according to the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when the negative voltage turn-off control is performed on the switching transistor by using the turn-off negative voltage interval, the switching transistor can be effectively prevented from being turned on mistakenly, and the switching transistor can be protected, which can prolong service life of the switching transistor.

Embodiments of the present disclosure further provide a computer-readable storage medium, having a program for determining a turn-off negative voltage of a switching transistor stored thereon. The program for determining the turn-off negative voltage of the switching transistor, when executed by a processor, implements the method for determining the turn-off negative voltage of the switching transistor according to any one of the above-mentioned embodiments.

In the computer-readable storage medium according to the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when the negative voltage turn-off control is performed on the switching transistor by using the turn-off negative voltage interval, the switching transistor can be effectively prevented from being turned on mistakenly, and the switching transistor can be protected, which can prolong service life of the switching transistor.

Embodiments of the present disclosure further provide a switching transistor drive control circuit. The switching transistor drive control circuit includes a drive power supply, a drive unit, and a control unit. The control unit is configured to acquire a turn-off negative voltage interval of a switching transistor by implementing the method for determining the turn-off negative voltage of the switching transistor according to any one of the above-mentioned embodiments, and control the drive power supply based on the turn-off negative voltage interval to provide a negative turn-off voltage to the drive unit. The drive unit is configured to drive, in response to receiving a turn-off control signal, the switching transistor to be turned off based on the negative turn-off voltage.

In the switching transistor drive control circuit according to the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when the negative voltage turn-off control is performed on the switching transistor by using the turn-off negative voltage interval, the switching transistor can be effectively prevented from being turned on mistakenly, and the switching transistor can be protected, which can prolong service life of the switching transistor.

In some embodiments of the present disclosure, the drive unit includes a drive chip and a first gate resistor. The drive chip has a positive power pin connected to a positive turn-on voltage supply terminal of the drive power supply, a negative power pin connected to a negative turn-off voltage supply terminal of the drive power supply, and an input pin connected to the control unit to receive the turn-off control signal sent by the control unit. The first gate resistor has a terminal connected to an output pin of the drive chip and another terminal connected to a gate of the switching transistor.

In some embodiments of the present disclosure, the drive unit further includes a first diode and a second gate resistor. The first diode has a cathode connected to a terminal of the first gate resistor. The second gate resistor has a terminal connected to an anode of the first diode and another terminal connected to the other terminal of the first gate resistor.

In some embodiments of the present disclosure, the drive unit further includes a second diode. The second diode has a cathode connected to the terminal of the first gate resistor and an anode connected to the cathode of the first diode.

In some embodiments of the present disclosure, the drive unit further includes a first diode and a second gate resistor. The first diode has a cathode connected to the terminal of the first gate resistor and an anode connected to the other terminal of the first gate resistor. The second gate resistor has a terminal connected to an anode of the first diode, and another terminal connected to the gate of the switching transistor.

In some embodiments of the present disclosure, the drive unit further includes a first coupling capacitor and a second coupling capacitor. The first coupling capacitor has a terminal connected to a positive turn-on voltage supply terminal of the drive power supply. The second coupling capacitor has a terminal connected to another terminal of the first coupling capacitor, and another terminal connected to a negative turn-off voltage supply terminal of the drive power supply.

In some embodiments of the present disclosure, when the switching transistor is an upper bridge switching transistor, a node between the first coupling capacitor and the second coupling capacitor is connected to a midpoint of a bridge arm at which the upper bridge switching transistor is located. When the switching transistor is a lower bridge switching transistor, the node between the first coupling capacitor and the second coupling capacitor is grounded.

Embodiments of the present disclosure further provide a motor control system. The motor control system includes the switching transistor drive control circuit according to any one of the above-mentioned embodiments.

In the motor control system according to the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when the negative voltage turn-off control is performed on the switching transistor by using the turn-off negative voltage interval, the switching transistor can be effectively prevented from being turned on mistakenly, and the switching transistor can be protected, which can prolong service life of the switching transistor.

Embodiments of the present disclosure further provide a compressor. The compressor includes the motor control system according to any one of the above-mentioned embodiments.

In the compressor according to the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when the negative voltage turn-off control is performed on the switching transistor by using the turn-off negative voltage interval, the switching transistor can be effectively prevented from being turned on mistakenly, and the switching transistor can be protected, which can prolong service life of the switching transistor.

Embodiments of the present disclosure further provide a vehicle. The vehicle includes the compressor according to any one of the above-mentioned embodiments.

In the vehicle according to the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when the negative voltage turn-off control is performed on the switching transistor by using the turn-off negative voltage interval, the switching transistor can be effectively prevented from being turned on mistakenly, and the switching transistor can be protected, which can prolong service life of the switching transistor.

Additional aspects and advantages of the embodiments of the present disclosure will be given at least in part in the following description, or become apparent at least in part from the following description, or can be learned from practicing of the embodiments of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic flowchart showing a method for determining a turn-off negative voltage of a switching transistor according to an embodiment of the present disclosure.

FIG. 2 is a schematic scene graph showing a method for determining a turn-off negative voltage of a switching transistor according to an embodiment of the present disclosure.

FIG. 3 is a schematic scene graph showing a method for determining a turn-off negative voltage of a switching transistor according to another embodiment of the present disclosure.

FIG. 4 is a schematic flowchart showing a method for determining a turn-off negative voltage of a switching transistor according to another embodiment of the present disclosure.

FIG. 5 is a structural block diagram showing an apparatus for determining a turn-off negative voltage of a switching transistor according to an embodiment of the present disclosure.

FIG. 6 is a structural block diagram showing an inverter according to an embodiment of the present disclosure.

FIG. 7 is a structural block diagram showing a switching transistor drive control circuit according to an embodiment of the present disclosure.

FIG. 8 is a schematic circuit view showing a switching transistor drive control circuit according to an embodiment of the present disclosure.

FIG. 9 is a schematic circuit view showing a switching transistor drive control circuit according to another embodiment of the present disclosure.

FIG. 10 is a schematic circuit view showing a switching transistor drive control circuit according to another embodiment of the present disclosure.

FIG. 11 is a schematic circuit view showing a switching transistor drive control circuit according to another embodiment of the present disclosure.

FIG. 12 is a structural block diagram showing a motor control system according to an embodiment of the present disclosure.

FIG. 13 is a structural block diagram showing a compressor according to an embodiment of the present disclosure.

FIG. 14 is a structural block diagram showing a vehicle according to an embodiment of the present disclosure.

### DETAILED DESCRIPTION OF EMBODIMENTS

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limiting, the present disclosure.

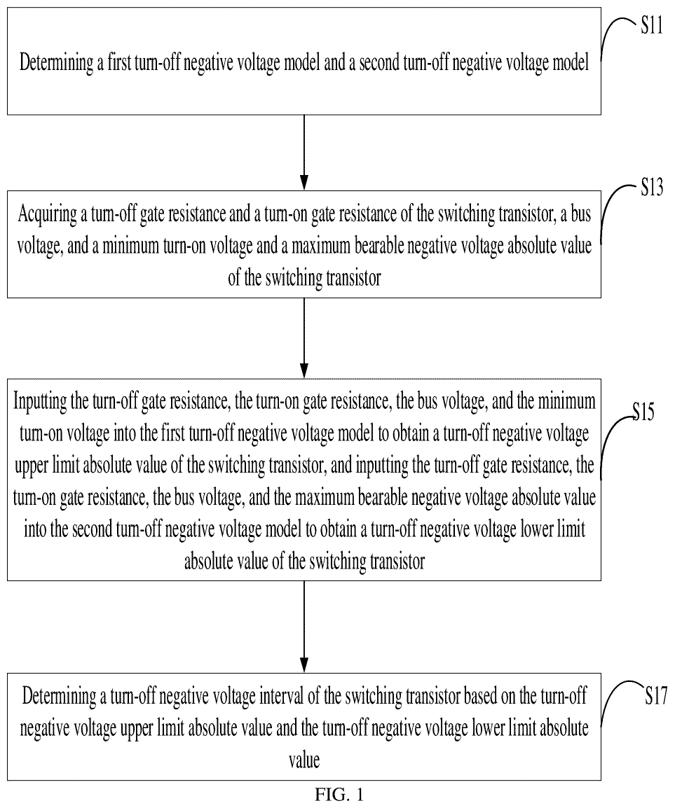

In order to clearly explain a method and apparatus for determining a turn-off negative voltage of a switching transistor, and a switching transistor drive control circuit according to the embodiments of the present disclosure, a description will be made in conjunction with a schematic flowchart of a method for determining a turn-off negative voltage of a switching transistor shown in FIG. 1. As shown in FIG. 1, the method for determining the turn-off negative voltage of the switching transistor according to the embodiments of the present disclosure includes operations at blocks S11 to S17.

At block S11, a first turn-off negative voltage model and a second turn-off negative voltage model are determined.

At block S13, a turn-off gate resistance and a turn-on gate resistance of the switching transistor, a bus voltage, and a minimum turn-on voltage and a maximum bearable negative voltage absolute value of the switching transistor are acquired.

At block S15, the turn-off gate resistance, the turn-on gate resistance, the bus voltage, and the minimum turn-on voltage are inputted into the first turn-off negative voltage model to obtain a turn-off negative voltage upper limit absolute value of the switching transistor, and the turn-off gate resistance, the turn-on gate resistance, the bus voltage, and the maximum bearable negative voltage absolute value are inputted into the second turn-off negative voltage model to obtain a turn-off negative voltage lower limit absolute value of the switching transistor.

At block S17, a turn-off negative voltage interval of the switching transistor is determined based on the turn-off negative voltage upper limit absolute value and the turn-off negative voltage lower limit absolute value.

In the method for determining the turn-off negative voltage of the switching transistor according to the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when a negative voltage turn-off control is performed on the switching transistor by using the turn-off negative voltage interval, the switching transistor can be effectively prevented from being turned on mistakenly, and the switching transistor can be protected, which can prolong service life of the switching transistor.

It may be understood that although the method of applying the turn-off negative voltage to the gate can prevent the switching transistor from being turned on mistakenly, in a case where the turn-off negative voltage upper limit absolute value is set too low, the switching transistor may still be turned on mistakenly in some cases, and in a case where the turn-off negative voltage lower limit absolute value is set too high, a negative voltage spike value may exceed an allowable driving negative voltage lower limit absolute value of the switching transistor, reducing life of the switching transistor and even causing damage to the switch. Therefore, the turn-off negative voltage interval of the switching transistor needs to be accurately determined.

In an exemplary embodiment of the present disclosure, the first turn-off negative voltage model can determine the turn-off negative voltage upper limit absolute value of the switching transistor. An expression form of the first turn-off negative voltage model includes, but is not limited to, a neural network model, a data mapping graph/table, a mathematical relational expression, and the like. When the first turn-off negative voltage model is the neural network model, inputs of the neural network model may include the turn-off gate resistance, the turn-on gate resistance, the bus voltage, and the minimum turn-on voltage of the switching transistor, and outputs of the neural network model may include the turn-off negative voltage upper limit absolute value of the switching transistor. As a result, after the turn-off gate resistance, the turn-on gate resistance, the bus voltage, and the minimum turn-on voltage of the switching transistor are acquired, the turn-off gate resistance, the turn-on gate resistance, the bus voltage, and the minimum turn-on voltage are inputted into the neural network model, to quickly obtain corresponding relatively accurate turn-off negative voltage upper limit absolute value of the switching transistor. When the first turn-off negative voltage model is the data mapping graph/table, the data mapping graph/table may include predetermined turn-off gate resistances, turn-on gate resistances, and bus voltages of different switching transistors, and turn-off negative voltage upper limit absolute values corresponding to minimum turn-on voltages of the different transistors. As a result, after the turn-off gate resistance, the turn-on gate resistance, the bus voltage, and the minimum turn-on voltage of the switching transistor are acquired, corresponding relatively accurate turn-off negative voltage upper limit absolute value of the switching transistor can be quickly obtained by finding the data mapping map/table. When the first turn-off negative voltage model is the mathematical relational expression, the mathematical relational expression can reflect a relationship between the turn-off gate resistance, the turn-on gate resistance, the bus voltage, and the minimum turn-on voltage of the switching transistor and the turn-off negative voltage upper limit absolute value of the switching transistor. As a result, after the turn-off gate resistance, the turn-on gate resistance, the bus voltage, and the minimum turn-on voltage of the switching transistor are acquired, the corresponding turn-off negative voltage upper limit absolute value of the switching transistor can be obtained from the mathematical relationship expression.

The second turn-off negative voltage model can determine the turn-off negative voltage lower limit absolute value of the switching transistor. An expression form of the second turn-off negative voltage model includes, but is not limited to, a neural network model, a data mapping graph/table, a mathematical relational expression, and the like. When the second turn-off negative voltage model is the neural network model, inputs of the neural network model may include the turn-off gate resistance, the turn-on gate resistance, the bus voltage, and the maximum bearable negative voltage absolute value of the switching transistor, and outputs of the neural network model may include the turn-off negative voltage lower limit absolute value of the switching transistor. As a result, after the turn-off gate resistance, the turn-on gate resistance, the bus voltage, and the maximum bearable negative voltage absolute value of the switching transistor are acquired, the turn-off gate resistance, the turn-on gate resistance, the bus voltage, and the maximum bearable negative voltage absolute value are inputted into the neural network model, to quickly obtain corresponding relatively accurate turn-off negative voltage lower limit absolute value of the switching transistor. When the second turn-off negative voltage model is the data mapping graph/table, the data mapping graph/table may include predetermined turn-off gate resistances, turn-on gate resistances, and bus voltages of different switching transistors, and turn-off negative voltage lower limit absolute values corresponding to maximum bearable negative voltage absolute values of the different switching transistors. As a result, after the turn-off gate resistance, the turn-on gate resistance, the bus voltage, and the maximum bearable negative voltage absolute value of the switching transistor are acquired, corresponding relatively accurate turn-off negative voltage lower limit absolute value of the switching transistor can be quickly obtained by finding the data mapping map/table. When the second turn-off negative voltage model is the mathematical relational expression, the mathematical relational expression can reflect a relationship between the turn-off gate resistance, the turn-on gate resistance, the bus voltage, and the maximum bearable negative voltage absolute value of the switching transistor and the turn-off negative voltage lower limit absolute value of the switching transistor. As a result, after the turn-off gate resistance, the turn-on gate resistance, the bus voltage, and the maximum bearable negative voltage absolute value of the switching transistor are acquired, the corresponding turn-off negative voltage lower limit absolute value of the switching transistor can be obtained from the mathematical relationship expression.

In some embodiments, the first turn-off negative voltage model and the corresponding second turn-off negative voltage model may be determined based on a model of the switching transistor, respectively. The first turn-off negative voltage model of the switching transistors of indifferent models may have the same or different expression forms, and the second turn-off negative voltage model of the switching transistors of different models may have the same or different expression forms, which are not limited herein. In some embodiments, the first turn-off negative voltage model and the second turn-off negative voltage model of the switching transistor of a same model have a same form.

It should be noted that the turn-off negative voltage is negative, and the turn-off negative voltage interval may be understood as a value interval of the turn-off negative voltage. That is, all of numerical values in the turn-off negative voltage interval are negative.

In some embodiments of the present disclosure, the first turn-off negative voltage model is expressed as: V_{SS_min}=λ₁*f₁(R_{G_on}, R_{G_off}, V_{DC})−Vₜₕ, i.e. equation (1), where V_{SS_min} represents the turn-off negative voltage upper limit absolute value, λ₁ represents a first derating parameter, f (R_{G_on}, R_{G_off}, V_{DC}) represents a function expression corresponding to the first turn-off negative voltage model, R_{G_on} represents the turn-on gate resistance, R_{G_off} represents the turn-off gate resistance, V_{DC} represents the bus voltage, and Vₜₕ represents the minimum turn-on voltage.

In this way, a relationship between the turn-on gate resistance and the turn-on gate resistance of the switching transistor, the bus voltage, and the minimum turn-on voltage of the switching transistor and the turn-off negative voltage upper limit absolute value of the switching transistor can be clearly expressed by the above equation (1).

In an exemplary embodiment of the present disclosure, the turn-off gate resistance may be understood as a total resistance of a turn-off circuit when the switching transistor is turned off, and the turn-on gate resistance may be understood as a total resistance of a turn-on circuit when the switching transistor is turned on. In some embodiments, the minimum turn-on voltage may be obtained by querying corresponding data based on a specific model of the switching transistor. In some embodiments, the first derating parameter may be obtained by querying corresponding derating criteria based on a specific model of the resistor. In some embodiments, the bus voltage may be obtained by a bus voltage measurement device.

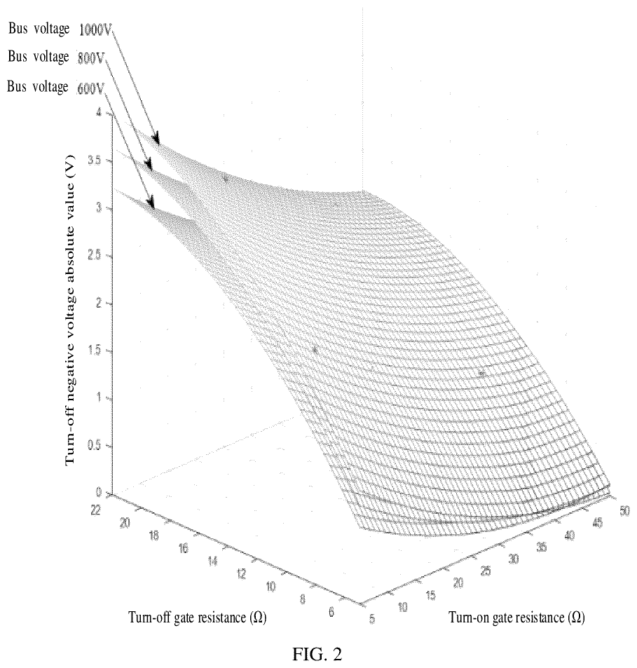

In some embodiments, a relationship between the turn-off negative voltage upper limit absolute value and the turn-on gate resistance, the turn-off gate resistance, and the bus voltage is shown in FIG. 2. It should be understood that when the turn-on gate resistance, the turn-off gate resistance, and the bus voltage input into the first turn-off negative voltage model change, the turn-off negative voltage upper limit absolute value output from the first turn-off negative voltage model will also change accordingly. Further, different turn-on gate resistances, different turn-off gate resistances, different bus voltages, and corresponding turn-off negative voltage upper limit absolute values, which are obtained through extensive simulation experiments, are substituted into the above equation (1) to obtain multiple different polynomials. After polynomial fitting, a specific expression of the first turn-off negative voltage model can be expressed as V_{SS_min}=b₂*R_{G_on}+b₃*R_{G_off}+b₄*V_{DC}+b₅*R_{G_on}²+b₆*R_{G_off}+b₇*V_{DC}²+b₈*R_{G_on}*R_{G_off}+b₉*R_{G_off}*V_{DC}+b₁₀*R_{G_off}*V_{DC}−Vₜₕ, i.e. equation (2), where b₂=−24.41, b₃=63.47, b₄=222.4, b₅=0.555, b₆=1.033, b₇=−8.683, b₈=−1.096, b₉=6.276, and b₁₀=−2.759.

In an example, the minimum turn-on voltage of the switching transistor is 1.5 V, and the bus voltage is 900 V. The selected turn-on gate resistance is 40Ω, and the selected turn-off gate resistance is 20Ω. By using the equation (2), it is obtained that the turn-off negative voltage upper limit absolute value is 2.44 V. That is, the turn-off negative voltage of the switching transistor should be smaller than −2.44 V.

In some embodiments of the present disclosure, the second turn-off negative voltage model is expressed as V_{SS_max}-V_{GS_max}−λ₂*f₂(R_{G_on}, R_{G_off}, V_{DC}), i.e., equation (3), where V_{SS_max} is the turn-off negative voltage lower limit absolute value, λ₂ is a second derating parameter, f₂(R_{G_on}, R_{G_off}, V_{DC}) is a function expression corresponding to the second turn-off negative voltage model, R_{G_on} is the turn-on gate resistance, R_{G_off} is the turn-off gate resistance, V_{DC} is the bus voltage, and V_{GS_max} is the maximum bearable negative voltage absolute value.

Thus, a relationship between the turn-off gate resistance, the turn-on gate resistance, the bus voltage, and the maximum bearable negative voltage absolute value of the switching transistor and the turn-off negative voltage lower limit absolute value of the switching transistor can be clearly expressed by the above equation (3).

In an exemplary embodiment of the present disclosure, the turn-off gate resistance may be understood as the total resistance of the turn-off circuit when the switching transistor is turned off, and the turn-on gate resistance may be understood as the total resistance of the turn-on circuit when the switching transistor is turned on. In some embodiments, the maximum bearable negative voltage absolute value may be obtained by querying corresponding data based on a specific model of the switching transistor. In some embodiments, the second derating parameter may be obtained by querying corresponding derating criteria based on a specific model of the resistor. In some embodiments, the bus voltage may be obtained by the bus voltage measurement device.

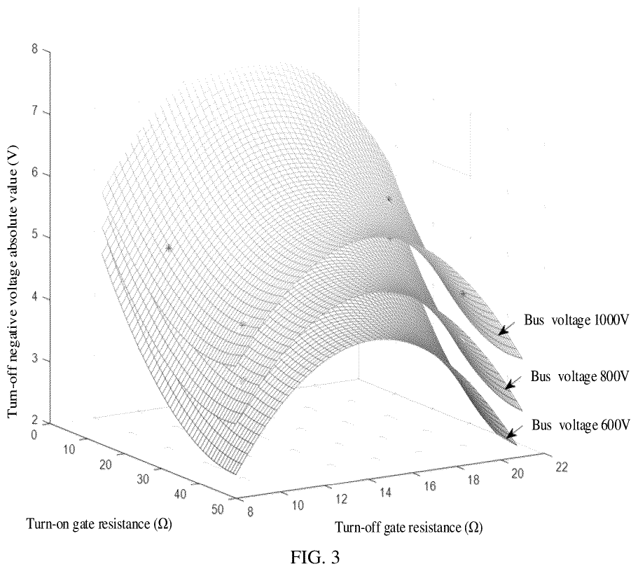

In some embodiments, a relationship between the turn-off negative voltage lower limit absolute value and the turn-on gate resistance, the turn-off gate resistance, and the bus voltage is shown in FIG. 3. It should be understood that when the turn-on gate resistance, the turn-off gate resistance, and the bus voltage input by the second turn-off negative voltage model change, the turn-off negative voltage lower limit absolute value output from the second turn-off negative voltage model will also change accordingly. Further, different turn-on gate resistances, different turn-off gate resistances, different bus voltages, and corresponding turn-off negative voltage upper lower absolute values are substituted into the above equation (3) to obtain multiple different polynomials. After polynomial fitting, a specific expression of the second turn-off negative voltage model may be expressed as V_{SS_max}=V_{GS_max}+d₂*R_{G_on}+d₃*R_{G_off}+d₄*V_{DC}+d₅*R_{G_on}²+d₆*R_{G_off}²+d₇*V_{DC}²+d₈*R_{G_on}*R_{G_off}+d₉*R_{G_off}*V_{DC}+d₁₀*R_{G_off}*V_{DC}, i.e. equation (4), where d₂=−122.9, d₃=1454.0, d₄=−488.3, d₅=2.069, d₆=−47.87, d₇=15.43, d₈=−0.805, d₉=3.800, and d₁₀=−5.223.

In an example, the maximum bearable negative voltage of the switching transistor is −9V That is, the switching transistor maximum bearable negative voltage absolute value is 9V. The bus voltage is 900 V, the selected turn-on gate resistance is 40Ω, and the selected turn-off gate resistance is 20Ω. By using the equation (4), it is obtained that the turn-off negative voltage lower limit absolute value is 4.96 V. That is, the turn-off negative voltage of the switching transistor should be greater than −4.96 V.

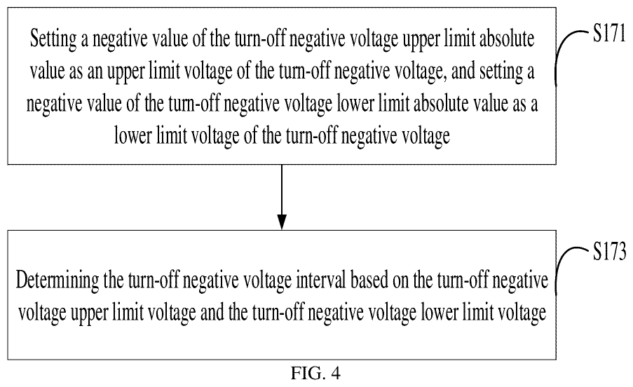

Referring to FIG. 4, in some embodiments of the present disclosure, the operation at block S17 further includes operations at blocks S171 and S173.

At block S171, a negative value of the turn-off negative voltage upper limit absolute value is set as a turn-off negative voltage upper limit voltage, and a negative value of the turn-off negative voltage lower limit absolute value is set as a lower limit voltage of the turn-off negative voltage.

At block S173, the turn-off negative voltage interval is determined based on the upper limit voltage of the turn-off negative voltage and the lower limit voltage of the turn-off negative voltage.

In this way, the turn-off negative voltage interval of the switching transistor can be accurately obtained. When a voltage of the gate of the switching transistor is within the turn-off negative voltage interval, the switching transistor can be turned off, effectively preventing the switching transistor from being turned on mistakenly.

In an exemplary embodiment of the present disclosure, the turn-off negative voltage upper limit absolute value may be understood as an upper limit of an absolute value of the turn-off negative voltage, and the turn-off negative voltage lower limit absolute value may be understood as a lower limit of an absolute value of the turn-off negative voltage. That is, both the turn-off negative voltage upper limit absolute value and the turn-off negative voltage lower limit absolute value are positive, and the turn-off negative voltage of the switching transistor is negative. Therefore, a negative value of the turn-off negative voltage upper limit absolute value is set as the upper limit voltage of the turn-off negative voltage, and a negative value of the turn-off negative voltage lower limit absolute value is set as the lower limit voltage of the turn-off negative voltage, and then the turn-off negative voltage interval is determined based on the lower limit voltage of the turn-off negative voltage and the upper limit voltage of the turn-off negative voltage. In this way, it can be ensured that the turn-off negative voltage of the selected switching transistor is greater than or equal to the lower limit voltage of the turn-off negative voltage, and the turn-off negative voltage of the switching transistor is smaller than or equal to the upper limit voltage of the turn-off negative voltage.

In an example, the minimum turn-on voltage of the switching transistor may be 1.5 V, and the maximum bearable negative voltage of the switching transistor is−9 V. That is, the maximum bearable negative voltage absolute value of the switching transistor is 9 V. The bus voltage may be 900 V. The selected turn-on gate resistance is 40Ω, and the selected turn-off gate resistance is 20Ω. By using the equation (2), it is obtained that the turn-off negative voltage upper limit absolute value is 2.44 V. That is, the upper limit voltage of the turn-off negative voltage of the switching transistor is −2.44 V. By using the equation (4), it is obtained that the turn-off negative voltage lower limit absolute value of the switching transistor is 4.96 V. That is, the lower limit voltage of the turn-off negative voltage of the switching transistor is −4.96 V Thus, the turn-off negative voltage interval of the switching transistor can be determined as [−4.96 V, −2.44V].

In some embodiments of the present disclosure, the switching transistor is a silicon-carbide Metal Oxide Semiconductor (MOS) transistor.

Therefore, the turn-off negative voltage interval can be accurately determined based on the above method, thereby effectively preventing the silicon carbide MOS transistor from being turned on mistakenly, protecting the silicon carbide MOS transistor, and prolonging the service life of the silicon carbide MOS transistor. It should be understood that the silicon carbide MOS transistor is more likely to be turned on mistakenly due to its fast speed and a low minimum turn-on voltage.

It should be noted that the specific numerical values mentioned above are only for the purpose of illustrating the embodiments of the present disclosure in detail by way of example, and should not be construed as limitations on the present disclosure. In other examples or embodiments, other numerical values may be selected in accordance with the present disclosure, and the present disclosure is not limited in this regard.

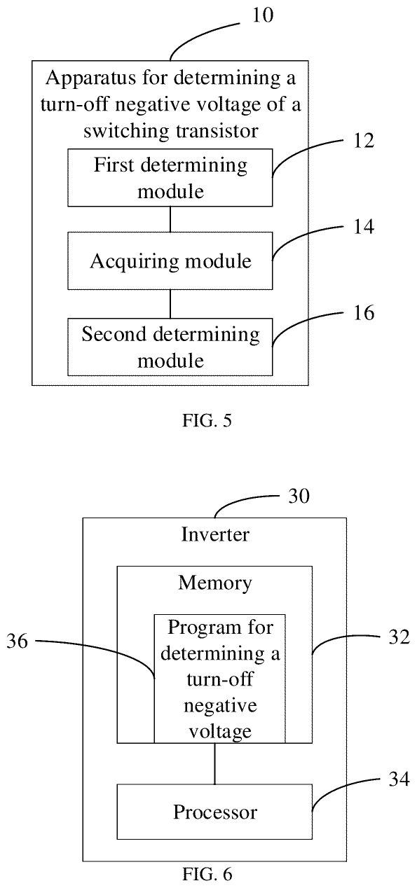

In order to implement the above embodiments, embodiments of the present disclosure further provide an apparatus for determining a turn-off negative voltage of a switching transistor. The apparatus can implement the method for determining the turn-off negative voltage of the switching transistor according to any of the above embodiments. FIG. 5 is a block diagram of an apparatus for determining a turn-off negative voltage of a switching transistor according to an embodiment of the present disclosure. As shown in FIG. 5, an apparatus 10 for determining a turn-off negative voltage of a switching transistor according to an embodiment of the present disclosure includes a first determining module 12, an acquiring module 14, and a second determining module 16. The first determining module 12 is configured to determine a first turn-off negative voltage model and a second turn-off negative voltage model. The acquiring module 14 is configured to acquire a turn-off gate resistance and a turn-on gate resistance of the switching transistor, a bus voltage, and a minimum turn-on voltage and a maximum bearable negative voltage absolute value of the switching transistor. The second determining module 16 is configured to: input the turn-off gate resistance, the turn-on gate resistance, the bus voltage, and the minimum turn-on voltage into the first turn-off negative voltage model to obtain a turn-off negative voltage upper limit absolute value of the switching transistor; input the turn-off gate resistance, the turn-on gate resistance, the bus voltage, and the maximum bearable negative voltage absolute value into the second turn-off negative voltage model to obtain a turn-off negative voltage lower limit absolute value of the switching transistor; and determine a turn-off negative voltage interval of the switching transistor based on the turn-off negative voltage upper limit absolute value and the turn-off negative voltage lower limit absolute value.

In the apparatus 10 for determining the turn-off negative voltage of the switching transistor according to the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when a negative voltage turn-off control is performed on the switching transistor by using the turn-off negative voltage interval, the switching transistor can be effectively prevented from being turned on mistakenly, and the switching transistor can be protected, which can prolong service life of the switching transistor.

In some embodiments of the present disclosure, the first turn-off negative voltage model is expressed as V_{SS_min}=λ₁*f₁(R_{G_on}, R_{G_off}, V_{DC})−Vₜₕ, i.e. equation (1), where V_{SS_min} represents the turn-off negative voltage upper limit absolute value, λ₁ represents a first derating parameter, f₁(R_{G_on}, R_{G_off}, V_{DC}) represents a function expression corresponding to the first turn-off negative voltage model, R_{G} on represents the turn-on gate resistance, R_{G_off} represents the turn-off gate resistance, V_{DC} represents the bus voltage, and Vₜₕ is the minimum turn-on voltage.

In some embodiments of the present disclosure, the second turn-off negative voltage model is expressed as V_{SS_max}=V_{GS_max}−λ₂*f₂(R_{G_on}, R_{G_off}, V_{DC}), i.e. equation (3), where V_{SS_max} represents the turn-off negative voltage lower limit absolute value, λ₂ represents a second derating parameter, f₂(R_{G_on}, R_{G_off}, V_{DC}) represents a function expression corresponding to the second turn-off negative voltage model, R_{G_on} represents the turn-on gate resistance, R_{G_off} represents the turn-off gate resistance, V_{DC} represents the bus voltage, and V_{GS_max} represents the maximum bearable negative voltage absolute value.

In some embodiments of the present disclosure, the second determination module 16 includes a first determination unit and a second determination unit. The first determination unit is configured to set a negative value of the turn-off negative voltage upper limit absolute value as a turn-off negative voltage upper limit voltage, and set a negative value of the turn-off negative voltage lower limit absolute value as a lower limit voltage of the turn-off negative voltage. The second determination unit is configured to determine the turn-off negative voltage interval based on the lower limit voltage of the turn-off negative voltage and the upper limit voltage of the turn-off negative voltage.

In some embodiments of the present disclosure, the switching transistor is the silicon-carbide MOS transistor.

It should be noted that the explanatory description of the embodiments and beneficial effects of the method for determining the turn-off negative voltage of the switching transistor is also adapted to the apparatus 10 for determining the turn-off negative voltage of the switching transistor of the present disclosure, and thus the detailed description thereof will be omitted herein to avoid redundancy.

In order to implement the above embodiments, embodiments of the present disclosure further provide an inverter, which can implement the method for determining the turn-off negative voltage of the switching transistor according to any one of the above embodiments. FIG. 6 is a block diagram of an inverter according to an embodiment of the present disclosure. As shown in FIG. 6, an inverter 30 includes a memory 32, a processor 34, and a program 36 for determining a turn-off negative voltage of a switching transistor stored in the memory 32 and executable on the processor 34. The processor 34 is configured to implement, when executing the program 36 for determining the turn-off negative voltage of the switching transistor, the method for determining the turn-off negative voltage of the switching transistor according to any one of the embodiments described above.

In the inverter 30 according to the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when a negative voltage turn-off control is performed on the switching transistor by using the turn-off negative voltage interval, the switching transistor can be effectively prevented from being turned on mistakenly, and the switching transistor can be protected, which can prolong service life of the switching transistor.

For example, the processor 34 is configured to implement, when the program 36 for determining the turn-off negative voltage of the switching transistor is executed by processor 34, operations at blocks at S11 to S17 of the method for determining the turn-off negative voltage of the switching transistor.

At block S11, a first turn-off negative voltage model and a second turn-off negative voltage model are determined.

At block S13, a turn-off gate resistance and a turn-on gate resistance of the switching transistor, a bus voltage, and a minimum turn-on voltage and a maximum bearable negative voltage absolute value of the switching transistor are acquired.

At block S15, the turn-off gate resistance, the turn-on gate resistance, the bus voltage, and the minimum turn-on voltage are inputted into the first turn-off negative voltage model to obtain a turn-off negative voltage upper limit absolute value of the switching transistor, and the turn-off gate resistance, the turn-on gate resistance, the bus voltage, and the maximum bearable negative voltage absolute value are inputted into the second turn-off negative voltage model to obtain a turn-off negative voltage lower limit absolute value of the switching transistor.

At block S17, a turn-off negative voltage interval of the switching transistor is determined based on the turn-off negative voltage upper limit absolute value and the turn-off negative voltage lower limit absolute value.

It should be noted that the explanatory description of the embodiments and beneficial effects of the method for determining the turn-off negative voltage of the switching transistor is also adapted to the inverter 30 of the present disclosure, and thus the detailed description thereof will be omitted herein to avoid redundancy.

In order to implement the above embodiments, embodiments of the present disclosure further provide a computer-readable storage medium having a program for determining a turn-off negative voltage of a switching transistor stored thereon. The program for determining the turn-off negative voltage of the switching transistor, when executed by a processor, implements the method for determining the turn-off negative voltage of the switching transistor according to any one of the above embodiments.

In the computer-readable storage medium of the embodiments of the present disclosure, the turn-off negative voltage upper limit absolute value of the switching transistor is obtained by inputting the acquired turn-off gate resistance, turn-on gate resistance, bus voltage, and minimum turn-on voltage of the switching transistor into the first turn-off negative voltage model, and the turn-off negative voltage lower limit absolute value of the switching transistor is obtained by inputting the acquired turn-off gate resistance, turn-on gate resistance, bus voltage, and maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when a negative voltage turn-off control is performed on the switching transistor by using the turn-off negative voltage interval, the switching transistor can be effectively prevented from being turned on mistakenly, and the switching transistor can be protected, which can prolong service life of the switching transistor.

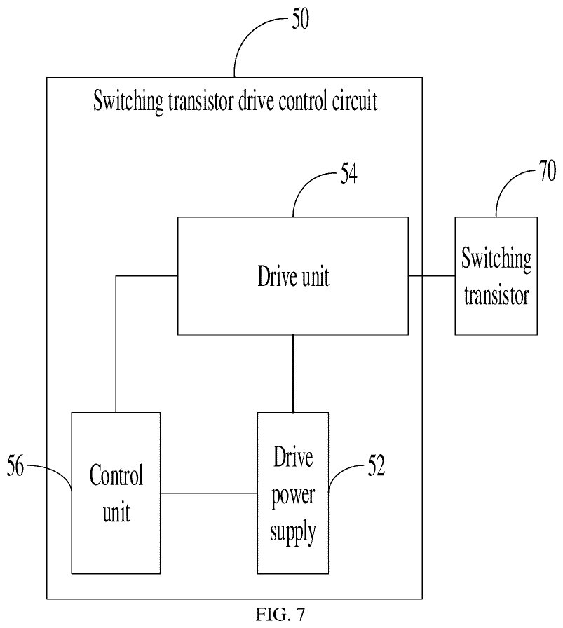

In order to implement the above embodiments, embodiments of the present disclosure further provide a switching transistor drive control circuit. FIG. 7 is a schematic circuit diagram of a switching transistor drive control circuit according to an embodiment of the present disclosure. As shown in FIG. 7, a switching transistor drive control circuit 50 includes a drive power supply 52, a drive unit 54, and a control unit 56. The control unit 56 is configured to acquire a turn-off negative voltage interval of a switching transistor 70 by implementing the method for determining the turn-off negative voltage of the switching transistor 70 according to any one of the embodiments described above, and control the drive power supply 52 to provide a negative turn-off voltage to the drive unit 54 based on the turn-off negative voltage interval. The drive unit 54 is configured to drive, in response to receiving a turn-off control signal, the switching transistor 70 to be turned off based on the negative turn-off voltage.

In the switching transistor drive control circuit 50 according to the embodiments of the present disclosure, the turn-off negative voltage upper limit absolute value of the switching transistor 70 is obtained by inputting the acquired turn-off gate resistance, turn-on gate resistance, bus voltage, and minimum turn-on voltage of the switching transistor 70 into the first turn-off negative voltage model, and the turn-off negative voltage lower limit absolute value of the switching transistor 70 is obtained by inputting the acquired turn-off gate resistance, turn-on gate resistance, bus voltage, and maximum bearable negative voltage absolute value of the switching transistor 70 into the second turn-off negative voltage model. Then, the turn-off negative voltage interval of the switching transistor 70 is accurately determined based on the turn-off negative voltage upper limit absolute value of the switching transistor 70 and the turn-off negative voltage lower limit absolute value of the switching transistor 70. Therefore, when a negative voltage turn-off control is performed on the switching transistor 70 by using the turn-off negative voltage interval, the switching transistor 70 can be effectively prevented from being turned on mistakenly, and the switching transistor 70 can be protected, which can prolong service life of the switching transistor 70.

In some embodiments, the control unit 56 may be a Micro Control Unit (MCU).

In some embodiments of the present disclosure, the drive unit 54 includes a first coupling capacitor and a second coupling capacitor. The first coupling capacitor has a terminal connected to a positive turn-on voltage supply terminal of the drive power supply. The second coupling capacitor has a terminal connected to another terminal of the first coupling capacitor, and another terminal connected to a negative turn-off voltage supply terminal of the drive power supply.

Thus, the positive turn-on voltage supply terminal and the negative turn-off voltage supply terminal of the drive power supply are isolated by the first coupling capacitor and the second coupling capacitor.

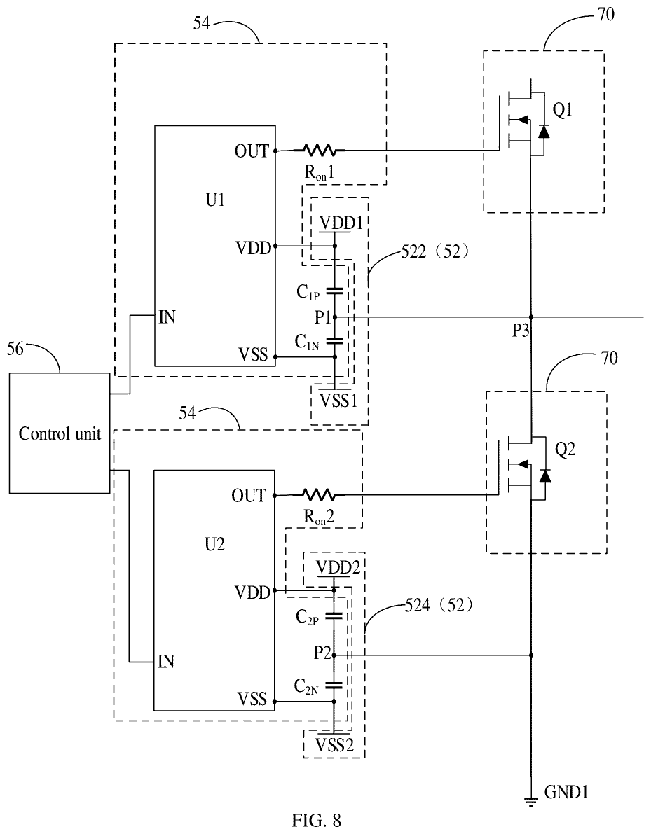

In an example, referring to FIG. 8, the first coupling capacitor includes a capacitor C_{1P} and a capacitor C_{2P}. The second coupling capacitor includes a capacitor C_{1N} and a capacitor C_{2N}. The drive power supply 52 includes a first drive power supply 522 and a second drive power supply 524. The capacitor C_{1P} has a terminal connected to a positive turn-on voltage supply terminal VDD1 of the first drive power supply 522. Another terminal of the capacitor C_{1P} is connected to a terminal of the capacitor C_{1N}, and the capacitor C_{1P} has a first node P1. The capacitor C_{1N} has another terminal connected to a negative turn-off voltage supply terminal VSS1 of the first drive power supply 522. The capacitor C_{2P} has a terminal connected to a positive turn-on voltage supply terminal VDD2 of the second drive power supply 524. Another terminal of is connected to a terminal of the capacitor C_{2N}, and the capacitor C_{2P} has a second node P2. The capacitor C_{2N} has another terminal connected to a negative turn-off voltage supply terminal VSS2 of the second drive power supply 524.

In some embodiments of the present disclosure, when the switching transistor 70 is an upper bridge switching transistor, a node between the first coupling capacitor and the second coupling capacitor is connected to a midpoint of a bridge arm at which the upper bridge switching transistor is located. When the switching transistor 70 is a lower bridge switching transistor, a node between the first coupling capacitor and the second coupling capacitor is grounded.

In this way, in a bridge inverter circuit, by using the switching transistor drive control circuit 50, the switching transistor can be accurately turned off, thereby effectively preventing the switching transistor 70 from being turned on mistakenly, protecting the switching transistor 70, and prolonging service life of the switching transistor 70. It should be understood that the bridge inverter circuit may include a single-phase full-bridge inverter circuit, a three-phase bridge inverter circuit, or bridge inverter circuits of other topologies.

In an example, referring to FIG. 8, the switching transistor 70 includes an upper bridge switching transistor Q1 and a lower bridge switching transistor Q2. A source of the upper bridge switching transistor Q1 is connected to a drain of the lower bridge switching transistor Q2, and the upper bridge switching transistor Q1 has a third node P3. When the switching transistor 70 is the upper bridge switching transistor Q1, a first node P1 between the first coupling capacitor C_{1P} and the second coupling capacitor C_{1N} is connected to a midpoint (i.e., a third node P3) of the bridge arm at which the upper bridge switching transistor Q1 is located. When the switching transistor 70 is the lower bridge switching transistor Q2, a second node P2 between the first coupling capacitor C_{2P} and the second coupling capacitor C_{2N} is grounded.

In some embodiments of the present disclosure, the drive unit 54 includes a drive chip and a first gate resistor. The drive chip has a positive power pin connected to the positive turn-on voltage supply terminal of the drive power supply, a negative power pin connected to the negative turn-off voltage supply terminal of the drive power supply, and an input pin connected to the control unit to receive a turn-off control signal sent by the control unit. The first gate resistor has a terminal connected to the output pin of the drive chip, and another terminal connected to a gate of the switching transistor.

In this way, the drive chip can drive the switching transistor to be turned on or off by the first gate resistor.

In an example, referring to FIG. 8, the drive chip includes a chip U1 and a chip U2. The first gate resistor includes a resistor Rₒₙ1 and a resistor Rₒₙ2. The drive power supply 52 includes a first drive power supply 522 and a second drive power supply 524. The switching transistor 70 includes an upper bridge switching transistor Q1 and a lower bridge switching transistor Q2. The first coupling capacitor includes a capacitor C_{1P} and a capacitor C_{2P}. The second coupling capacitor includes a capacitor C_{1N} and a capacitor C_{2N}.

The drive chip U1 has a positive power pin VDD connected to a positive turn-on voltage supply terminal VDD1 of the first drive power supply 522. The drive chip U1 has a negative power pin VSS connected to a negative turn-off voltage supply terminal VSS1 of the first drive power supply 522. The drive chip U1 has an input pin IN connected to a first terminal of the control unit 56 to receive a turn-off control signal sent by the control unit 56. The drive chip U1 has an output pin OUT connected to a terminal of the resistor Rₒₙ1. The resistor Rₒₙ1 has another terminal connected to a gate of the upper bridge switching transistor Q1. A source of the upper bridge switching transistor Q1 is connected to a drain of the lower bridge switching transistor Q2, and the upper bridge switching transistor Q1 has a third node P3. The capacitor C_{1P} has a terminal connected to the positive turn-on voltage supply terminal VDD1 of the first drive power supply 522. Another terminal of the capacitor C_{1P} is connected to a terminal of the capacitor C_{1N}, and the capacitor C_{1P} has a first node P1. The first node P1 is connected to the third node P3. The capacitor C_{1N} has another terminal connected to the negative turn-off voltage supply terminal VSS1 of the first drive power supply 522.

The drive chip U2 has a positive power pin VDD connected to a positive turn-on voltage supply terminal VDD2 of the second drive power supply 524. The drive chip U2 has a negative power pin VSS connected to a negative turn-off voltage supply terminal VSS2 of the second drive power supply 524. The drive chip U2 has an input pin IN connected to a second terminal of the control unit 56 to receive the turn-off control signal sent by the control unit 56. The drive chip U2 has an output pin OUT connected to a terminal of the resistor Rₒₙ2. The resistor Rₒₙ2 has another terminal connected to a gate of the lower bridge switching transistor Q2. A drain of the lower bridge switching transistor Q2 is connected to the source of the upper bridge switching transistor Q1, and a source of the lower bridge switching transistor Q2 is grounded. The capacitor C_{2P} has a terminal connected to the positive turn-on voltage supply terminal VDD2 of the second drive power supply 524. Another terminal of the capacitor C_{2P} is connected to a terminal of the capacitor C_{2N}, and the capacitor C_{2P} has a second node P2. The second node P2 is grounded. The capacitor C_{2N} has another terminal connected to the negative turn-off voltage supply terminal VSS2 of the second drive power supply 524.

When the control unit 56 sends the turn-on control signal through the first terminal, the positive power pin VDD of the drive chip U1 is in communication with the output pin OUT of the drive chip U1. The first drive power supply 522 provides a positive voltage to the positive power pin VDD of the drive chip U1, and the OUT pin of the drive chip U1 outputs the positive voltage. After voltage division by the resistor Rₒₙ1, a positive turn-on voltage is provided for the gate of the upper bridge switching transistor Q1, and the upper bridge switching transistor Q1 is turned on. It should be understood that the turn-on gate resistance is the resistor Rₒₙ1 in this case. When the control unit 56 sends a turn-off control signal through the first terminal, the negative power pin VSS of the drive chip U1 is in communication with the output pin OUT of the drive chip U1. The first drive power supply 522 provides a negative voltage to the negative power pin VSS of the drive chip U1, and the OUT pin of the drive chip U1 outputs the negative voltage. After voltage division by the resistor Rₒₙ1, a negative turn-off voltage is provided for the gate of the upper bridge switching transistor Q1, and the upper bridge switching transistor Q1 is turned off. It should be understood that the turn-off gate resistance is a resistance value of the resistor Rₒₙ1 in this case.

When the control unit 56 sends a turn-on control signal through the second terminal, the positive power pin VDD of the drive chip U2 is in communication with the output pin OUT of the drive chip U2. The second drive power supply 524 provides a positive voltage to the positive power pin VDD of the drive chip U2, and the OUT pin of the drive chip U2 outputs the positive voltage. After voltage division by the resistor Rₒₙ2, a positive turn-on voltage is provided for the gate of the lower bridge switching transistor Q2, and the lower bridge switching transistor Q2 is turned on. It should be understood that the turn-on gate resistance is the resistor Rₒₙ2 in this case. When the control unit 56 sends a turn-off control signal through the second terminal, the negative power pin VSS of the drive chip U2 is in communication with the output pin OUT of the drive chip U2. The second drive power supply 524 provides a negative voltage to the drive chip U2, and the OUT pin of the drive chip U2 outputs the negative voltage. After voltage division by the resistor Rₒₙ2, a negative turn-off voltage is provided for the gate of the lower bridge switching transistor Q2, and the lower bridge switching transistor Q2 is turned off. It should be understood that the turn-off gate resistance is a resistance value of the resistor Rₒₙ2 in this case.

In some embodiments of the present disclosure, the drive unit 54 further includes a first diode and a second gate resistor. The first diode has a cathode connected to a terminal of the first gate resistor. The second gate resistor has a terminal connected to an anode of the first diode, and another terminal connected to the other terminal of the first gate resistor.

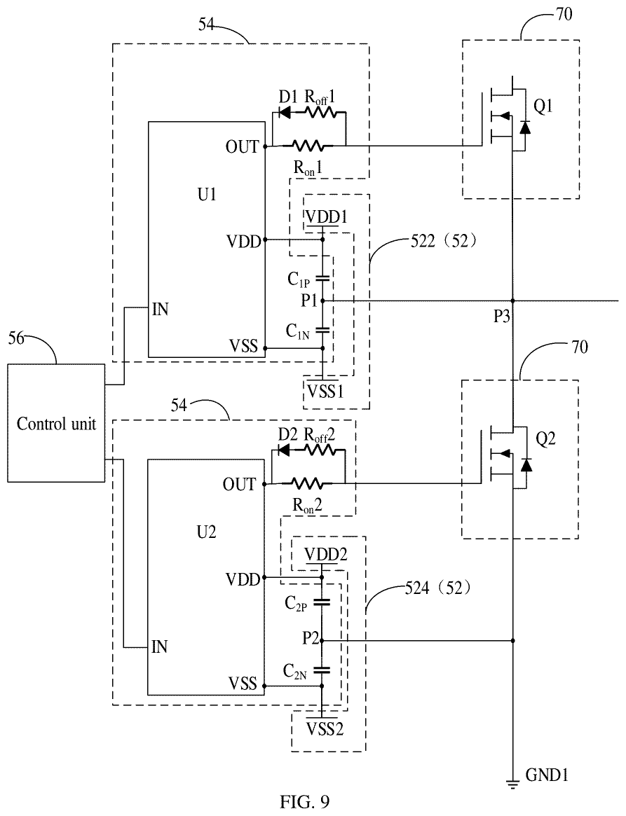

In an example, referring to FIG. 9, the drive chip includes a chip U1 and a chip U2. The first gate resistor includes a resistor Rₒₙ1 and a resistor Rₒₙ2. The second gate resistor includes a resistor R_{off}1 and a resistor R_{off}2. The drive power supply 52 includes a first drive power supply 522 and a second drive power supply 524. The switching transistor 70 includes an upper bridge switching transistor Q1 and a lower bridge switching transistor Q2. The first coupling capacitor includes a capacitor C_{1P} and a capacitor C_{2P}. The second coupling capacitor includes a capacitor C_{1N} and a capacitor C_{2N}. The first diode includes a diode D1 and a diode D2.

The drive chip U1 has a positive power pin VDD connected to a positive turn-on voltage supply terminal VDD1 of the first drive power supply 522. The drive chip U1 has a negative power pin VSS connected to a negative turn-off voltage supply terminal VSS1 of the first drive power supply 522. The drive chip U1 has an input pin IN connected to a first terminal of the control unit 56 to receive a turn-off control signal sent by the control unit 56. The drive chip U1 has an output pin OUT connected to a terminal of the resistor Rₒₙ1. The resistor Rₒₙ1 has another terminal connected to a gate of the upper bridge switching transistor Q1. A source of the upper bridge switching transistor Q1 is connected to a drain of the lower bridge switching transistor Q2, and the upper bridge switching transistor Q1 has a third node P3. A cathode of the diode D1 is connected to a terminal of the resistor Rₒₙ1, and an anode of the diode D1 is connected to a terminal of the resistor R_{off}1. The resistor R_{off}1 has another terminal connected to another terminal of the resistor Rₒₙ1. The capacitor C_{1P} has a terminal connected to the positive turn-on voltage supply terminal VDD1 of the first drive power supply 522. Another terminal of the capacitor C_{1P} is connected to a terminal of the capacitor C_{1N}, and the capacitor C_{1P} has a first node P1. The first node P1 is connected to a third node P3. The capacitor C_{1N} has another terminal connected to the negative turn-off voltage supply terminal VSS1 of the first drive power supply 522.

The drive chip U2 has a positive power pin VDD connected to a positive turn-on voltage supply terminal VDD2 of the second drive power supply 524. The drive chip U2 has a negative power pin VSS connected to a negative turn-off voltage supply terminal VSS2 of the second drive power supply 524. The drive chip U2 has an input pin IN connected to a second terminal of the control unit 56 to receive a turn-off control signal sent by the control unit 56. The drive chip U2 has an output pin OUT connected to a terminal of the resistor Rₒₙ2. The resistor Rₒₙ2 has another terminal connected to a gate of the lower bridge switching transistor Q2. A drain of the lower bridge switching transistor Q2 is connected to a source of the upper bridge switching transistor Q1, and a source of the lower bridge switching transistor Q2 is grounded. A cathode of the diode D2 is connected to a terminal of the resistor Rₒₙ2, and an anode of the diode D2 is connected to a terminal of the resistor R_{off}2. The resistor R_{off}2 has another terminal connected to another terminal of the resistor Rₒₙ2. The capacitor C_{2P} has a terminal connected to the positive turn-on voltage supply terminal VDD2 of the second drive power supply 524. Another terminal of the capacitor C_{2P} is connected to a terminal of the capacitor C_{2N}, and the capacitor C_{2P} has a second node P2. The second node P2 is grounded. The capacitor C_{2N} has another terminal connected to the negative turn-off voltage supply terminal VSS2 of the second drive power supply 524.

When the control unit 56 sends a turn-on control signal through the first terminal, the positive power pin VDD of the drive chip U1 is in communication with the output pin OUT of the drive chip U1. The first drive power supply 522 provides a positive voltage to the positive power pin VDD of the drive chip U1, the OUT pin of the drive chip U1 outputs the positive voltage, and the diode D1 is turned off. After voltage division by the resistor Rₒₙ1, a positive turn-on voltage is provided for the gate of the upper bridge switching transistor Q1, and the upper bridge switching transistor Q1 is turned on. It should be understood that the turn-on gate resistance is the resistor Rₒₙ1 in this case. When the control unit 56 sends a turn-off control signal through the first terminal, the negative power pin VSS of the drive chip U1 is in communication with the output pin OUT of the drive chip U1. The first drive power supply 522 provides a negative voltage to the negative power pin VSS of the drive chip U1, the OUT pin of the drive chip U1 outputs the negative voltage, and the diode D1 is turned on. After the resistor Rₒₙ1 and the resistor R_{off}1 are connected in parallel, a negative turn-off voltage is provided for the gate of the upper bridge switching transistor Q1, and the upper bridge switching transistor Q1 is turned off. It should be understood that the turn-off gate resistance may be a resistance value of the connected resistor Rₒₙ1 and resistor R_{off}1 in parallel.

When the control unit 56 sends a turn-on control signal through the second terminal, the positive power pin VDD of the drive chip U2 is in communication with the output pin OUT of the drive chip U2. The second drive power supply 524 provides a positive voltage to the positive power pin VDD of the drive chip U2, the OUT pin of the drive chip U2 outputs the positive voltage, and the diode D2 is turned off. After voltage division by the resistor Rₒₙ2, a positive turn-on voltage is provided for the gate of the lower bridge switching transistor Q2, and the lower bridge switching transistor Q2 is turned on. It should be understood that the turn-on gate resistance is the resistor Rₒₙ2 in this case. When the control unit 56 sends a turn-off control signal through the second terminal, the negative power pin VSS of the drive chip U2 is in communication with the output pin OUT of the drive chip U2. The second drive power supply 524 provides a negative voltage to the drive chip U2, the OUT pin of the drive chip U2 outputs the negative voltage, and the diode D2 is turned on. After the resistor R_{off}2 and the resistor R_{off}2 are connected in parallel, a negative turn-off voltage is provided for the gate of the lower bridge switching transistor Q2, and the lower bridge switching transistor Q2 is turned off. It should be understood that the turn-off gate resistance may be a resistance value of the connected resistor Rₒₙ2 and resistor R_{off}2 in parallel.

It should be noted that the diode has a turn-on resistance when being turned on. In some embodiments, the turn-on resistance of the diode may be considered when calculating the turn-on gate resistance and the turn-off gate resistance.

In some embodiments of the present disclosure, the drive unit 54 further includes a second diode. The second diode has a cathode connected to the terminal of the first gate resistor and an anode connected to the cathode of the first diode.

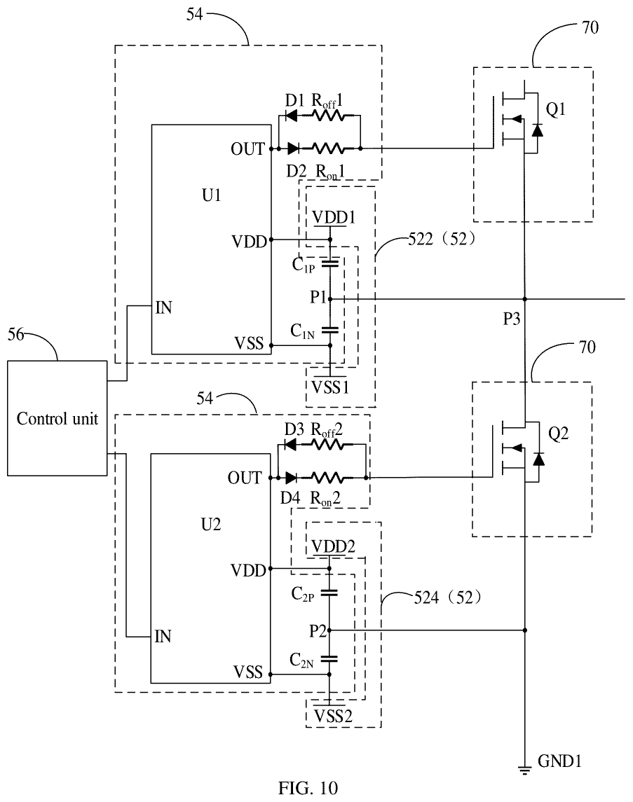

In an example, referring to FIG. 10, the drive chip includes a chip U1 and a chip U2. The first gate resistor includes a resistor Rₒₙ1 and a resistor Rₒₙ2. The second gate resistor includes a resistor R_{off}1 and a resistor R_{off}2. The drive power supply 52 includes a first drive power supply 522 and a second drive power supply 524. The switching transistor 70 includes an upper bridge switching transistor Q1 and a lower bridge switching transistor Q2. The first coupling capacitor includes a capacitor C_{1P} and a capacitor C_{2P}. The second coupling capacitor includes a capacitor C_{1N} and a capacitor C_{2N}. The first diode includes a diode D1 and a diode D3. The second diode includes a diode D2 and a diode D4.

The drive chip U1 has a positive power pin VDD connected to a positive turn-on voltage supply terminal VDD1 of the first drive power supply 522. The drive chip U1 has a negative power pin VSS connected to a negative turn-off voltage supply terminal VSS1 of the first drive power supply 522. The drive chip U1 has an input pin IN connected to a first terminal of the control unit 56 to receive a turn-off control signal sent by the control unit 56. The drive chip U1 has an output pin OUT connected to an anode of the diode D2. A cathode of the diode D2 is connected to a terminal of the resistor Rₒₙ1. The resistor Rₒₙ1 has another terminal connected to a gate of the upper bridge switching transistor Q1. A source of the upper bridge switching transistor Q1 is connected to a drain of the lower bridge switching transistor Q2, and the upper bridge switching transistor Q1 has a third node P3. A cathode of the diode D1 is connected to an anode of the diode D2. An anode of the diode D1 is connected to a terminal of the resistor R_{off}1. The resistor R_{off}1 has another terminal connected to another terminal of the resistor Rₒₙ1. The capacitor C_{1P} has a terminal connected to the positive turn-on voltage supply terminal VDD1 of the first drive power supply 522. Another terminal of the capacitor C_{1P} is connected to a terminal of the capacitor C_{1N}, and the capacitor C_{1P} has a first node P1. The first node P1 is connected to the third node P3. The capacitor C_{1N} has another terminal connected to the negative turn-off voltage supply terminal VSS1 of the first drive power supply 522.

The drive chip U2 has a positive power pin VDD connected to the positive turn-on voltage supply terminal VDD2 of the second drive power supply 524. The drive chip U2 has a negative power pin VSS connected to the negative turn-off voltage supply terminal VSS2 of the second drive power supply 524. The drive chip U2 has an input pin IN connected to a second terminal of the control unit 56 to receive the turn-off control signal sent by the control unit 56. The drive chip U2 has an output pin OUT connected to an anode of the diode D4. A cathode of diode D4 is connected to a terminal of resistor Rₒₙ2. The resistor Rₒₙ2 has another terminal connected to a gate of the lower bridge switching transistor Q2. A cathode of the diode D3 is connected to the anode of the diode D4. An anode of the diode D3 is connected to a terminal of the resistor R_{off}2. The resistor R_{off}2 has another terminal connected to another terminal of the resistor Rₒₙ2. The drain of the lower bridge switching transistor Q2 is connected to the source of the upper bridge switching transistor Q1, and the source of the lower bridge switching transistor Q2 is grounded. The capacitor C_{2P} has a terminal connected to the positive turn-on voltage supply terminal VDD2 of the second drive power supply 524. Another terminal of the capacitor C_{2P} is connected to a terminal of the capacitor C_{2N}, and the capacitor C_{2P} has a second node P2. The second node P2 is grounded. The capacitor C_{2N} has another terminal connected to the negative turn-off voltage supply terminal VSS2 of the second drive power supply 524.

When the control unit 56 sends a turn-on control signal through the first terminal, the positive power pin VDD of the drive chip U1 is in communication with the output pin OUT of the drive chip U1. The first drive power supply 522 provides a positive voltage to the positive power pin VDD of the drive chip U1, and the OUT pin of the drive chip U1 outputs the positive voltage. The diode D2 is turned on, and the diode D1 is turned off. After voltage division by the resistor Rₒₙ1, a positive turn-on voltage is provided for the gate of the upper bridge switching transistor Q1, and the upper bridge switching transistor Q1 is turned on. It should be understood that the turn-on gate resistance is the resistor Rₒₙ1 in this case. When the control unit 56 sends a turn-off control signal through the first terminal, the negative power pin VSS of the drive chip U1 is in communication with the output pin OUT of the drive chip U1. The first drive power supply 522 provides a negative voltage to the negative power pin VSS of the drive chip U1, and the OUT pin of the drive chip U1 outputs the negative voltage. The diode D1 is turned on, and the diode D2 is turned off. After voltage division by the resistor R_{off}1, a negative turn-off voltage is provided for the gate of the upper bridge switching transistor Q1, and the upper bridge switching transistor Q1 is turned off. It should be understood that the turn-off gate resistance is a resistance value of the resistor R_{off}1 in this case.

When the control unit 56 sends a turn-on control signal through the second terminal, the positive power pin VDD of the drive chip U2 is in communication with the output pin OUT of the drive chip U2. The second drive power supply 524 provides a positive voltage to the positive power pin VDD of the drive chip U2, and the OUT pin of the drive chip U2 outputs the positive voltage. The diode D4 is turned on, and the diode D3 is turned off. After voltage division by the resistor Rₒₙ2, a positive turn-on voltage is provided for the gate of the lower bridge switching transistor Q2, and the lower bridge switching transistor Q2 is turned on. It should be understood that at this time, the turn-on gate resistance is the resistor Rₒₙ2 in this case. When the control unit 56 sends a turn-off control signal through the second terminal, the negative power pin VSS of the drive chip U2 is in communication with the output pin OUT of the drive chip U2. The second drive power supply 524 provides a negative voltage to the drive chip U2, and the OUT pin of the drive chip U2 outputs the negative voltage. The diode D3 is turned on, and the diode D4 is turned off. After voltage division by the resistor R_{off}2, a negative turn-off voltage is provided for the gate of the lower bridge switching transistor Q2, and the lower bridge switching transistor Q2 is turned off. It should be understood that the turn-off gate resistance is a resistance value of the resistor R_{off}2 in this case.

It should be noted that the diode has a turn-on resistance when being turned on. In some embodiments, the turn-on resistance of the diode may be considered when calculating the turn-on gate resistance and the turn-off gate resistance.

In some embodiments of the present disclosure, the drive unit 54 further includes a first diode and a second gate resistor. The first diode has a cathode connected to the terminal of the first gate resistor and an anode connected to another terminal of the first gate resistor. The second gate resistor has a terminal connected to the anode of the first diode, and another terminal connected to the gate of the switching transistor.

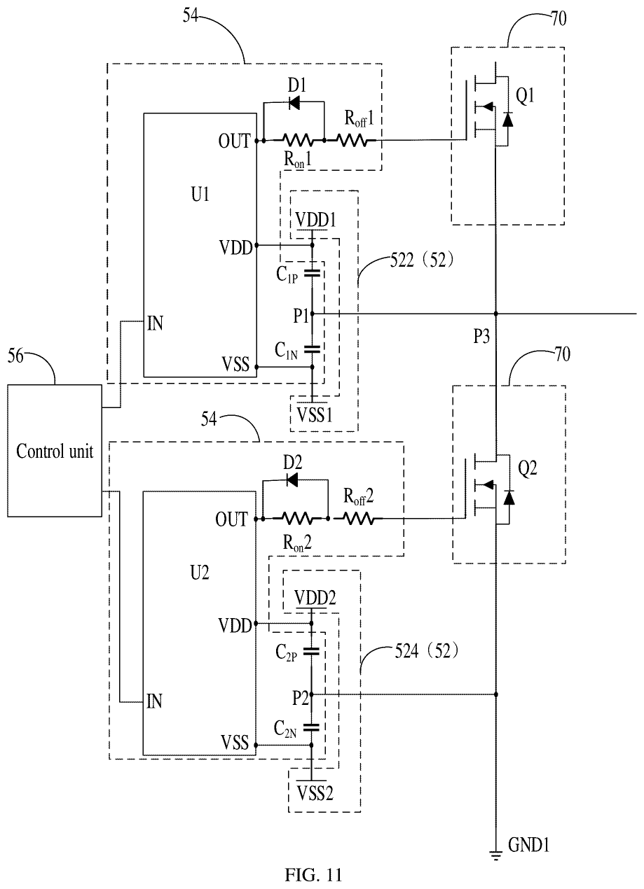

In an example, referring to FIG. 11, the drive chip includes a chip U1 and a chip U2. The first gate resistor includes a resistor Rₒₙ1 and a resistor Rₒₙ2. The second gate resistor includes a resistor R_{off}1 and the resistor R_{off}2. The drive power supply 52 includes a first drive power supply 522 and a second drive power supply 524. The switching transistor 70 includes an upper bridge switching transistor Q1 and a lower bridge switching transistor Q2. The first coupling capacitor includes a capacitor C_{1P} and a capacitor C_{2P}. The second coupling capacitor includes a capacitor C_{1N} and a capacitor C_{2N}. The first diode includes a diode D1 and a diode D2.

The drive chip U1 has a positive power pin VDD connected to a positive turn-on voltage supply terminal VDD1 of the first drive power supply 522. The drive chip U1 has a negative power pin VSS connected to a negative turn-off voltage supply terminal VSS1 of the first drive power supply 522. The drive chip U1 has an input pin IN connected to a first terminal of the control unit 56 to receive a turn-off control signal sent by the control unit 56. The drive chip U1 has an output pin OUT connected to a terminal of the resistor Rₒₙ1. The resistor Rₒₙ1 has another terminal connected to a terminal of the resistor R_{off}1. The resistor R_{off}1 has another terminal connected to a gate of the upper bridge switching transistor Q1. A source of the upper bridge switching transistor Q1 is connected to a drain of the lower bridge switching transistor Q2, and the upper bridge switching transistor Q1 has a third node P3. A cathode of the diode D1 is connected to a terminal of the resistor Rₒₙ1, and an anode of the diode D1 is connected to another terminal of the resistor Rₒₙ1. The capacitor C_{1P} has a terminal connected to the positive turn-on voltage supply terminal VDD1 of the first drive power supply 522. Another terminal of the capacitor C_{1P} is connected to a terminal of the capacitor C_{1N}, and the capacitor C_{1P} has a first node P1. The first node P1 is connected to the third node P3. The capacitor C_{1N} has another terminal connected to the negative turn-off voltage supply terminal VSS1 of the first drive power supply 522.

The drive chip U2 has a positive power pin VDD connected to the positive turn-on voltage supply terminal VDD2 of the second drive power supply 524. The drive chip U2 has a negative power pin VSS connected to the negative turn-off voltage supply terminal VSS2 of the second drive power supply 524. The drive chip U2 has an input pin IN connected to a second terminal of the control unit 56 to receive the turn-off control signal sent by the control unit 56. The drive chip U2 has an output pin OUT connected to a terminal of the resistor Rₒₙ2. The resistor Rₒₙ2 has another terminal connected to a terminal of the resistor R_{off}2. The resistor R_{off}2 has another terminal connected to the gate of the lower bridge switching transistor Q2. The drain of the lower bridge switching transistor Q2 is connected to the source of the upper bridge switching transistor Q1, and the source of the lower bridge switching transistor Q2 is grounded. A cathode of the diode D2 is connected to a terminal of the resistor Rₒₙ2, and an anode of the diode D2 is connected to a terminal of the resistor Rₒₙ2. The capacitor C_{2P} has a terminal connected to the positive turn-on voltage supply terminal VDD2 of the second drive power supply 524. Another terminal of the capacitor C_{2P} is connected to a terminal of the capacitor C_{2N}, the capacitor C_{2P} has a second node P2. The second node P2 is grounded. The capacitor C_{2N} has another terminal connected to the negative turn-off voltage supply terminal VSS2 of the second drive power supply 524.

When the control unit 56 sends a turn-on control signal through the first terminal, the positive power pin VDD of the drive chip U1 is in communication with the output pin OUT of the drive chip U1. The first drive power supply 522 provides a positive voltage to the positive power pin VDD of the drive chip U1, and the OUT pin of the drive chip U1 outputs the positive voltage. The diode D1 is turned off. After voltage division through the resistor Rₒₙ1 and the resistor R_{off}1 connected in series, a positive turn-on voltage is provided for the gate of the upper bridge switching transistor Q1, and the upper bridge switching transistor Q1 is turned on. It should be understood that, in this case, the turn-on gate resistance is a resistance value of the connected resistor Rₒₙ1 and resistor R_{off}1 in series. When the control unit 56 sends a turn-off control signal through the first terminal, the negative power pin VSS of the drive chip U1 is in communication with the output pin OUT of the drive chip U1. The first drive power supply 522 provides a negative voltage to the negative power pin VSS of the drive chip U1, and the OUT pin of the drive chip U1 outputs the negative voltage. The diode D1 is turned on, and the resistor Rₒₙ1 is short-circuited. After voltage division by the resistor R_{off}1, a negative turn-off voltage is provided for the gate of the upper bridge switching transistor Q1, and the upper bridge switching transistor Q1 is turned off. It should be understood that the turn-off gate resistance may be a resistance value of the resistor R_{off}1 in this case.

When the control unit 56 sends a turn-on control signal through the second terminal, the positive power pin VDD of the drive chip U2 is in communication with the output pin OUT of the drive chip U2. The second drive power supply 524 provides a positive voltage to the positive power pin VDD of the drive chip U2, and the OUT pin of the drive chip U2 outputs a positive voltage. The diode D2 is turned off. After voltage division through the connected resistor Rₒₙ1 and resistor R_{off}1 in series, a positive turn-on voltage is provided for the gate of the lower bridge switching transistor Q2, and the lower bridge switching transistor Q2 is turned on. It should be understood that, in this case, the turn-on gate resistance is a resistance value of the connected resistor Rₒₙ1 and resistor R_{off}1 in series. When the control unit 56 sends a turn-off control signal through the second terminal, the negative power pin VSS of the drive chip U2 is in communication with the output pin OUT of the drive chip U2. The second drive power supply 524 provides a negative voltage to the negative power pin VSS of the drive chip U2, and the OUT pin of the drive chip U2 outputs the negative voltage. The diode D2 is turned on, and the resistor Rₒₙ2 is short-circuited. After voltage division by the resistor R_{off}2, a negative turn-off voltage is provided for the gate of the lower bridge switching transistor Q2, and the lower bridge switching transistor Q2 is turned off. It should be understood that the turn-off gate resistance may be a resistance value of the resistor R_{off}2 in this case.

It should be noted that the diode has a turn-on resistance when being turned on. In some embodiments, the turn-on resistance of the diode may be considered when calculating the turn-on gate resistance and the turn-off gate resistance.

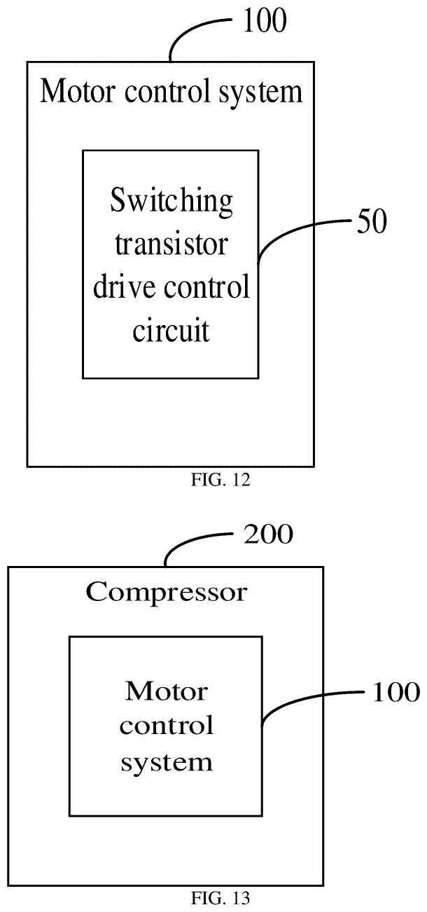

In order to implement the above embodiments, embodiments of the present disclosure further provide a motor control system. FIG. 12 is a structural block diagram of a motor control system according to an embodiment of the present disclosure. As shown in FIG. 12, the motor control system 100 includes the switching transistor drive control circuit 50 according to any one of the above embodiments.

In order to implement the above embodiments, embodiments of the present disclosure further provide a compressor. FIG. 13 is a structural block diagram of a compressor according to an embodiment of the present disclosure. As shown in FIG. 13, the compressor 200 includes the motor control system 100 according to the above embodiments.

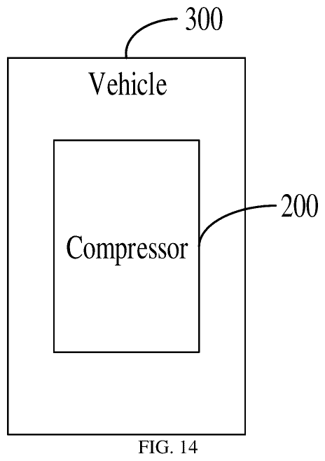

In order to implement the above embodiments, embodiments of the present disclosure further provide a vehicle. FIG. 14 is a structural block diagram of a vehicle according to an embodiment of the present disclosure. As shown in FIG. 14, the vehicle 300 includes the compressor 200 according to the above embodiments.

The vehicle 300 may be a new energy vehicle. In some embodiments, the new energy vehicle may be a pure electric vehicle using an electric motor as a main driving force. In other embodiments, the new energy vehicle may also be a hybrid vehicle using an internal combustion engine and an electric motor as main driving forces. With regard to the internal combustion engine and the electric motor for providing driving power for the new energy vehicle mentioned in the above embodiments, the internal combustion engine may employ gasoline, diesel oil, hydrogen, or the like as fuel, and the electric motor may employ a power battery, hydrogen fuel cell, or the like to providing electric energy, and the present disclosure is not limited in this regards. It should be noted that the embodiments are only an exemplary description of a structure of the new energy vehicle, and is not intended to limit the scope of the present disclosure.

In addition, in some embodiments, the compressor applicable to the new energy vehicle according to the embodiments of the present disclosure may be an electric compressor including a driving portion and a compression portion. The driving portion in the electric compressor is configured to drive the compression portion to perform a compression operation. For example, the driving portion may be a driving motor including a rotor and a stator. In addition, in some embodiments, the electric compressor may be a low back pressure compressor. The drive portion may be disposed at a low pressure chamber in communication with an intake port of the compressor. The compression portion may be disposed at a high pressure chamber in communication with an exhaust port of the compressor. Further, in some embodiments, the electric compressor may be a horizontal compressor, and the drive portion and the compression portion may be arranged transversely.

In the motor control system 100, the compressor 200, and the vehicle 300 according to the embodiments of the present disclosure, the turn-off negative voltage upper limit absolute value of the switching transistor is obtained by inputting the acquired turn-off gate resistance and turn-on gate resistance of the switching transitory, the acquired bus voltage, and the acquired minimum turn-on voltage of the switching transistor into the first turn-off negative voltage model, and a turn-off negative voltage lower limit absolute value of the switching transistor is obtained by inputting the acquired turn-off gate resistance and turn-on gate resistance, the acquired bus voltage, and the maximum bearable negative voltage absolute value of the switching transistor into the second turn-off negative voltage model. Then, the turn-off negative voltage interval of the switching transistor is accurately determined based on the turn-off negative voltage upper limit absolute value of the switching transistor and the turn-off negative voltage lower limit absolute value of the switching transistor. Therefore, when the negative voltage turn-off control is performed on the switching transistor by using the turn-off negative voltage interval, the switching transistor can be effectively prevented from being turned on mistakenly, and the switching transistor can be protected, which can prolong service life of the switching transistor.

It should be noted that the explanatory description of the embodiments and beneficial effects of the switching transistor drive control circuit is also adapted to the motor control system 100, the compressor 200, and the vehicle 300 of the present disclosure, and thus the detailed description thereof will be omitted herein to avoid redundancy.

Those skilled in the art should understand that the embodiments of the present disclosure can be provided as a method, a system, or a computer program product. Therefore, the present disclosure may adopt a form of a complete hardware embodiment, a complete software embodiment, or an embodiment combining software and hardware. In addition, the present disclosure may employ a form of a computer program product implemented on one or more computer-usable storage media (including but being not limited to disk storage, Compact Disc Read-Only Memory (CD-ROM), optical storage, etc.) containing computer-usable program codes.

The present disclosure is described with reference to flowcharts and/or block diagrams of the method, the device (system), and the computer program product according to the embodiments of the present disclosure. It should be understood that each process and/or block in the flowcharts and/or block diagrams, and a combination of processes and/or blocks in the flowcharts and/or block diagrams may be implemented by computer program instructions. These computer program instructions can be provided to a processor of a general-purpose computer, a special-purpose computer, an embedded processor, or other programmable data processing device to generate a machine, such that instructions executed by the processor of the computer or other programmable data processing devices generate an apparatus for implementing functions specified in one or more processes in the flowchart and/or one or more blocks in the block diagram.

These computer program instructions may further be stored in a computer-readable memory that can guide a computer or other programmable data processing devices to work in a specific manner, such that instructions stored in the computer-readable memory produce an article of manufacture including an instruction device. The instruction device implements functions specified in one or more processes in the flowchart and/or one or more blocks in the block diagram.

These computer program instructions can further be loaded on a computer or other programmable data processing devices to enable a series of operation steps to be executed on the computer or other programmable devices for producing computer-implemented processing, such that instructions executed on the computer or other programmable devices provide actions for implementing functions specified in one or more processes in the flowchart and/or one or more blocks in the block diagram.

In the description of this specification, description with reference to the terms “an embodiment”, “some embodiments”, “exemplary embodiments”, “examples” “specific examples”, or “some examples” etc., mean that specific features, structure, materials or characteristics described in conjunction with the embodiment or example are included in at least one embodiment or example of the present disclosure. In this specification, the schematic representations of the above terms do not necessarily refer to the same embodiment or example. Moreover, the described specific features, structures, materials, or characteristics may be combined in any one or more embodiments or examples in a suitable manner.

In addition, terms “first” and “second” are only used for descriptive purposes, and cannot be understood as indicating or implying relative importance or implicitly indicating the number of the indicated technical features. Therefore, the features associated with “first” and “second” may explicitly or implicitly include at least one of the features. In the description of the present disclosure, “plurality” means at least two, e.g., two, three, four, etc., unless otherwise specifically defined.

In the present disclosure, unless otherwise clearly specified and limited, terms such as “install”, “connect”, “connect to”, “fix” and the like should be understood in a broad sense. For example, it may be a fixed connection or a detachable connection or connection as one piece; mechanical connection or electrical connection; direct connection or indirect connection through an intermediate; internal communication of two components or the interaction relationship between two components, unless otherwise clearly limited. For those skilled in the art, the specific meaning of the above-mentioned terms in the present disclosure should be understood according to specific circumstances.

It should be noted that, in order to make the description simple, all possible combinations of the technical features in the foregoing embodiments are not described. However, as long as there is no conflict between the technical features in the embodiments, any combination of technical features in the above-described embodiments may be adopted, which should be considered in the scope of this specification.

Although embodiments of the present disclosure have been shown and described above, it should be understood that the above embodiments are merely exemplary, and cannot be construed as limitations of the present disclosure. For those skilled in the art, changes, alternatives, and modifications can be made to the above embodiments without departing from the scope of the present disclosure.

What is claimed is:

1. A method for determining a turn-off negative voltage of a switching transistor, comprising:
determining a first turn-off negative voltage model and a second turn-off negative voltage model;
acquiring a turn-off gate resistance and a turn-on gate resistance of the switching transistor, a bus voltage, and a minimum turn-on voltage and a maximum bearable negative voltage absolute value of the switching transistor;
inputting the turn-off gate resistance, the turn-on gate resistance, the bus voltage, and the minimum turn-on voltage into the first turn-off negative voltage model to obtain a turn-off negative voltage upper limit absolute value of the switching transistor, and inputting the turn-off gate resistance, the turn-on gate resistance, the bus voltage, and the maximum bearable negative voltage absolute value into the second turn-off negative voltage model to obtain a turn-off negative voltage lower limit absolute value of the switching transistor; and
determining a turn-off negative voltage interval of the switching transistor based on the turn-off negative voltage upper limit absolute value and the turn-off negative voltage lower limit absolute value.

2. The method according to claim 1, wherein the first turn-off negative voltage model is expressed as:
$${V}_{SS \_ min} = {λ}_{1} * {f}_{1} ( {R}_{G \_ on} , {R}_{G \_ off} , {V}_{DC} ) - {V}_{th} ,$$
where:
V_{SS_min} represents the turn-off negative voltage upper limit absolute value;
λ₁ represents a first derating parameter;
f₁(R_{G_on}, R_{G_off}, V_{DC}) represents a function expression corresponding to the first turn-off negative voltage model;
R_{G_on} represents the turn-on gate resistance;
R_{G_off} represents the turn-off gate resistance;
V_{DC} represents the bus voltage; and
Vₜₕ represents the minimum turn-on voltage.

3. The method according to claim 1, wherein the second turn-off negative voltage model is expressed as:
$${V}_{SS \_ max} = {V}_{GS \_ max} - {λ}_{2} * {f}_{2} ( {R}_{G \_ on} , {R}_{G \_ off} , {V}_{DC} ) ,$$
where:
V_{SS_max} represents the turn-off negative voltage lower limit absolute value;
λ₂ represents a second derating parameter;
f₂(R_{G_on}, R_{G_off}, V_{DC}) represents a function expression corresponding to the second turn-off negative voltage model;
R_{G_on} represents the turn-on gate resistance;
R_{G_off} represents the turn-off gate resistance;
V_{DC} represents the bus voltage; and
V_{GS_max} represents the maximum bearable negative voltage absolute value.

4. The method according to claim 1, wherein said determining the turn-off negative voltage interval of the switching transistor based on the turn-off negative voltage upper limit absolute value and the turn-off negative voltage lower limit absolute value comprises:
setting a negative value of the turn-off negative voltage upper limit absolute value as an upper limit voltage of the turn-off negative voltage, and setting a negative value of the turn-off negative voltage lower limit absolute value as a lower limit voltage of the turn-off negative voltage; and
determining the turn-off negative voltage interval based on the upper limit voltage of the turn-off negative voltage and the lower limit voltage of the turn-off negative voltage.

5. The method according to claim 1, wherein the switching transistor comprises a silicon-carbide Metal Oxide Semiconductor (MOS) transistor.

6. An apparatus for determining a turn-off negative voltage of a switching transistor, comprising at least one hardware processor configured to:
determine a first turn-off negative voltage model and a second turn-off negative voltage model;
acquire a turn-off gate resistance and a turn-on gate resistance of the switching transistor, a bus voltage, and a minimum turn-on voltage and a maximum bearable negative voltage absolute value of the switching transistor; and
input the turn-off gate resistance, the turn-on gate resistance, the bus voltage, and the minimum turn-on voltage into the first turn-off negative voltage model to obtain a turn-off negative voltage upper limit absolute value of the switching transistor; input the turn-off gate resistance, the turn-on gate resistance, the bus voltage, and the maximum bearable negative voltage absolute value into the second turn-off negative voltage model to obtain a turn-off negative voltage lower limit absolute value of the switching transistor; and determine a turn-off negative voltage interval of the switching transistor based on the turn-off negative voltage upper limit absolute value and the turn-off negative voltage lower limit absolute value.

7. An inverter comprising:
a memory;
at least one hardware processor; and
a program for determining a turn-off negative voltage of a switching transistor stored in the memory and executable on the at least one hardware processor,
wherein the at least one hardware processor is configured to implement, when executing the program for determining the turn-off negative voltage of the switching transistor, the method according to claim 1.

8. A non-transitory computer-readable storage medium, storing a program for determining a turn-off negative voltage of a switching transistor, wherein the program for determining the turn-off negative voltage of the switching transistor, when executed by at least one hardware processor, implements the method according to claim 1.

9. A switching transistor drive control circuit comprising:
a drive power supply;
a driver; and
a controller,
wherein:
the controller is configured to acquire a turn-off negative voltage interval of a switching transistor by implementing the method according to claim 1, and control the drive power supply to provide a negative turn-off voltage to the driver based on the turn-off negative voltage interval; and
the driver is configured to drive, in response to receiving a turn-off control signal, the switching transistor to be turned off based on the negative turn-off voltage.

10. The switching transistor drive control circuit according to claim 9, wherein the driver comprises:
a drive chip having a positive power pin connected to a positive turn-on voltage supply terminal of the drive power supply, a negative power pin connected to a negative turn-off voltage supply terminal of the drive power supply, and an input pin connected to the controller to receive the turn-off control signal sent by the controller; and
a first gate resistor having a terminal connected to an output pin of the drive chip, and another terminal connected to a gate of the switching transistor.

11. The switching transistor drive control circuit according to claim 10, wherein the driver further comprises:
a first diode having a cathode connected to a terminal of the first gate resistor; and
a second gate resistor having a terminal connected to an anode of the first diode, and another terminal connected to the other terminal of the first gate resistor.

12. The switching transistor drive control circuit according to claim 11, wherein the driver further comprises:
a second diode having a cathode connected to the a terminal of the first gate resistor and an anode connected to the cathode of the first diode.

13. The switching transistor drive control circuit according to claim 10, wherein the driver further comprises:
a first diode having a cathode connected to the a terminal of the first gate resistor and an anode connected to the other terminal of the first gate resistor; and
a second gate resistor having a terminal connected to an anode of the first diode, and another terminal connected to the gate of the switching transistor.

14. The switching transistor drive control circuit according to claim 9, wherein the driver further comprises:
a first coupling capacitor having a terminal connected to a positive turn-on voltage supply terminal of the drive power supply; and
a second coupling capacitor having a terminal connected to another terminal of the first coupling capacitor, and another terminal connected to a negative turn-off voltage supply terminal of the drive power supply.

15. The switching transistor drive control circuit according to claim 14, wherein:
when the switching transistor comprises an upper bridge switching transistor, a node between the first coupling capacitor and the second coupling capacitor is connected to a midpoint of a bridge arm at which the upper bridge switching transistor is located; and
when the switching transistor comprises a lower bridge switching transistor, a node between the first coupling capacitor and the second coupling capacitor is grounded.

16. A motor control system comprising the switching transistor drive control circuit according to claim 9.

17. A compressor comprising the motor control system according to claim 16.

18. A vehicle comprising the compressor according to claim 17.
